(19) United States
(12) Patent Application Publication
(10) Pub. No.: US 2014/0160703 A1
(43) Pub. Date: Jun. 12, 2014

(54) RISER CARD ASSEMBLY

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: YU-WEI HE, Shenzhen (CN); XIU-QUAN HU, Shenzhen (CN)

(73) Assignees: HON HAI PRECISION INDUSTRY CO., LTD., New Taipei (TW); HONG FU JIN PRECISION INDUSTRY (Shenzhen) CO., LTD, Shenzhen (CN)

(21) Appl. No.: 14/019,893

(22) Filed: Sep. 6, 2013

(30) Foreign Application Priority Data
Dec. 12, 2012 (CN) 2012105341183

(51) Int. Cl. H05K 7/12

(52) U.S. Cl. CPC H05K 7/12
USPC 361/759

(57) ABSTRACT

A riser card assembly includes a chassis, a bracket, a tray, a riser card, and a mounting member. The bracket is mounted to the chassis. The tray is located in the chassis. The tray includes a bottom plate and a protecting board extending from the bottom plate. The riser card includes an edge connector. The riser card is located on the tray and is substantially parallel to the bottom plate. The riser card is mounted to the chassis, and the protecting board is substantially flush with the edge connector. The mounting member is fixed to the riser card. The mounting member is fixed to the bracket. The protecting board is substantially flush with the edge connector to prevent the edge connector from interference.

### CROSS-REFERENCE TO RELATED APPLICATIONS

This application claims all benefits accruing under 35 U.S.C. §119 from China Patent Application No. 201210534118.3, filed on Dec. 12, 2012, in the China Intellectual Property Office, the contents of which are hereby incorporated by reference. Relevant subject matter is disclosed in co-pending U.S. Patent Applications entitled “RISER CARD ASSEMBLY,” Attorney Docket Number US48641, U.S. application Ser. No. ______, filed on ______.

### BACKGROUND

1. Technical Field

The present disclosure relates to riser card assemblies, and particular to a riser card assembly with a riser card.

2. Description of Related Art

In order to increase a number of expansion cards with different types of connectors to a motherboard of a computer, a riser card with a uniform output connector is provided to electronically connect the plurality of expansion cards to the motherboard. The riser card includes a printed circuit board, and a plurality of connectors located on outer edges of the printed circuit board to receive the expansion cards. However, the riser card is used alone, and a connector on outer edge of the riser card may interfere with other electronic components and cause damage after frequent use. Therefore, there is room for improvement within the art.

### BRIEF DESCRIPTION OF THE DRAWINGS

FIG. 1 is an exploded, isometric, cutaway view of one embodiment of a riser card assembly.

FIG. 2 is an assembled, cutaway view of the riser card assembly of FIG. 1.

FIG. 3 is an isometric view of the riser card assembly of FIG. 2.

FIG. 4 is similar to FIG. 3, but an expansion card is shown.

FIG. 5 is similar to FIG. 4, but shown from another aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

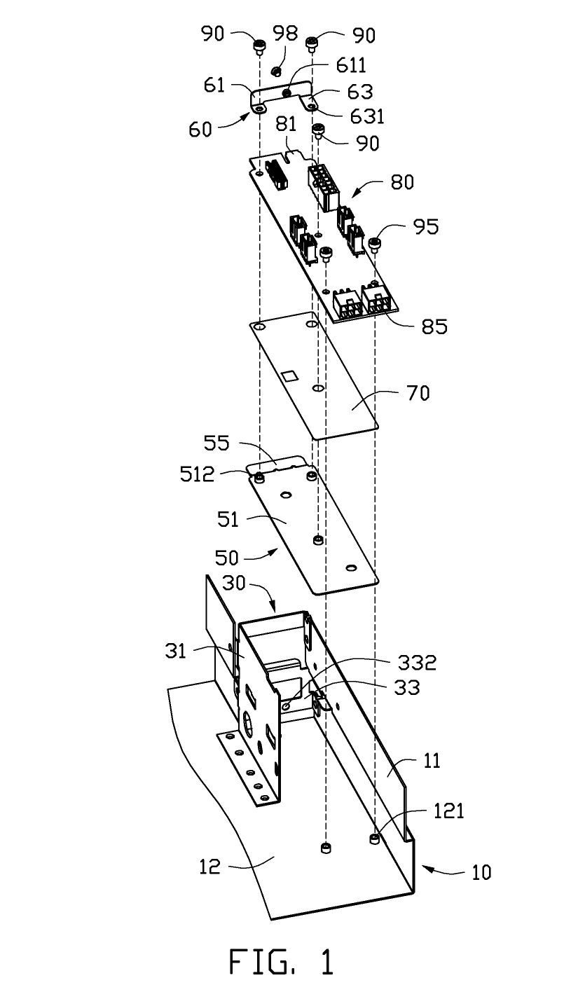

FIG. 1 illustrates one embodiment of a riser card assembly. The riser card assembly includes a chassis 10, a bracket 30 mounted to the chassis 10, a tray 50, a riser card 80, and a mounting member 60. An insulating sheet 70 may be located between the riser card 80 and the tray 50.

The chassis 10 includes a side wall 11 and a bottom wall 12, with two protruding first posts 121.

The bracket 30 includes a side panel 31 and a front panel 33. The side panel 31 is substantially parallel to the side wall 11. A fixing hole 332 is defined in the front panel 33. The front panel 33 is substantially perpendicular to the side panel 31.

The tray 50 includes a bottom plate 51 and a protecting board 55. The protecting board 55 extends from the bottom plate 51. The protecting board 55 and the bottom plate 51 are substantially located on a same plane. Three second posts 512 protrude from the bottom plate 51.

The riser card 80 includes an edge connector 81 and two plugs 85 located on opposite side of the edge connector 81.

The mounting member 60 includes a mounting tab 61 and two mounting feet 63. The two mounting feet 63 are spaced and are substantially perpendicular to the mounting tab 61. A screw hole 611 is defined in the mounting tab 61.

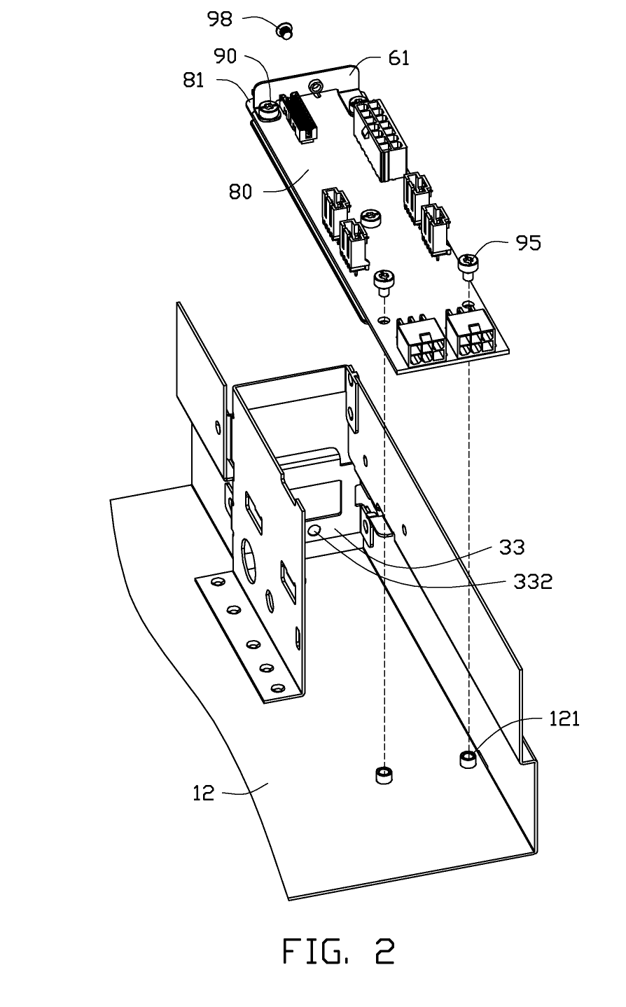

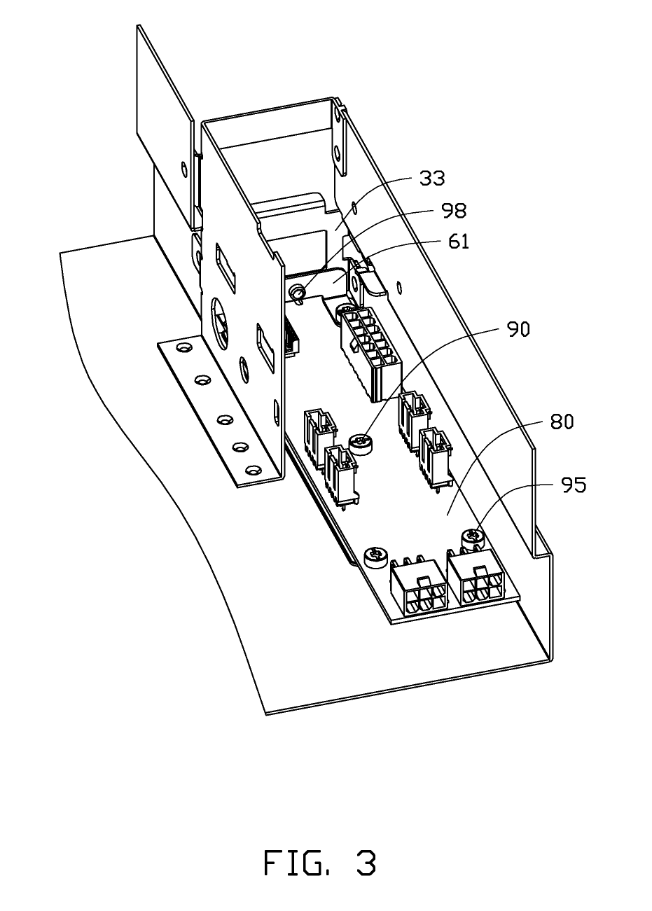

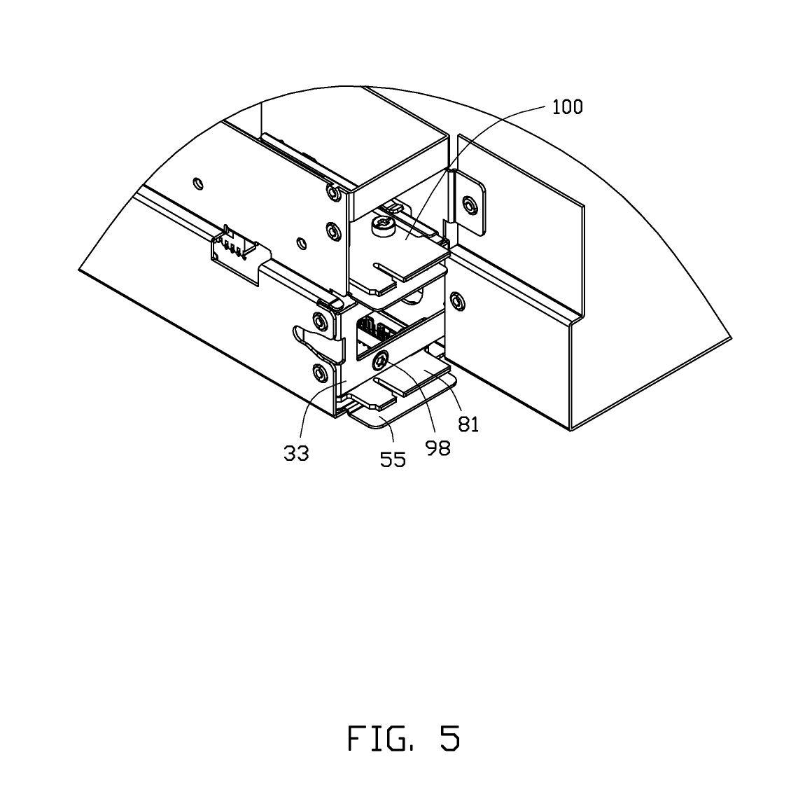

FIG. 2, FIG. 3 and FIG. 5 illustrate assembled views of the riser card assembly. In assembly, the insulating sheet 70 is located on the tray 50. The riser card 80 is fixed to the three second posts 512 through three first fasteners 90, and the two mounting feet 63 are fixed to the riser card 80 through two of the three first fasteners 90 at the same time. The mounting member 60 is adjacent to the edge connector 81 of the riser card 80. The riser card 80 and bottom plate 51 are spaced by the three posts 512. The protecting board 55 is substantially flush with the edge connecter 81 to prevent the edge connecter 81 from interference. The tray 50 and the riser card 80 are positioned on top of the bottom wall 12. The tray 50 and the riser card 80 are moved down into the bracket 30 along a direction substantially parallel to the side panel 31. When the tray 50 is received in the bracket 30 and reaches the bottom wall 12, the riser card 80 is mounted to the two first posts 121 through two second fasteners 95. The mounting tab 61 is then aligned with and fixed with the front panel 33 through a screw 98. Two opposites of the riser card 80 are mounted to the chassis 10 and the bracket 30. The protecting board 55 and the edge connector 81 extend out of the front panel 33.

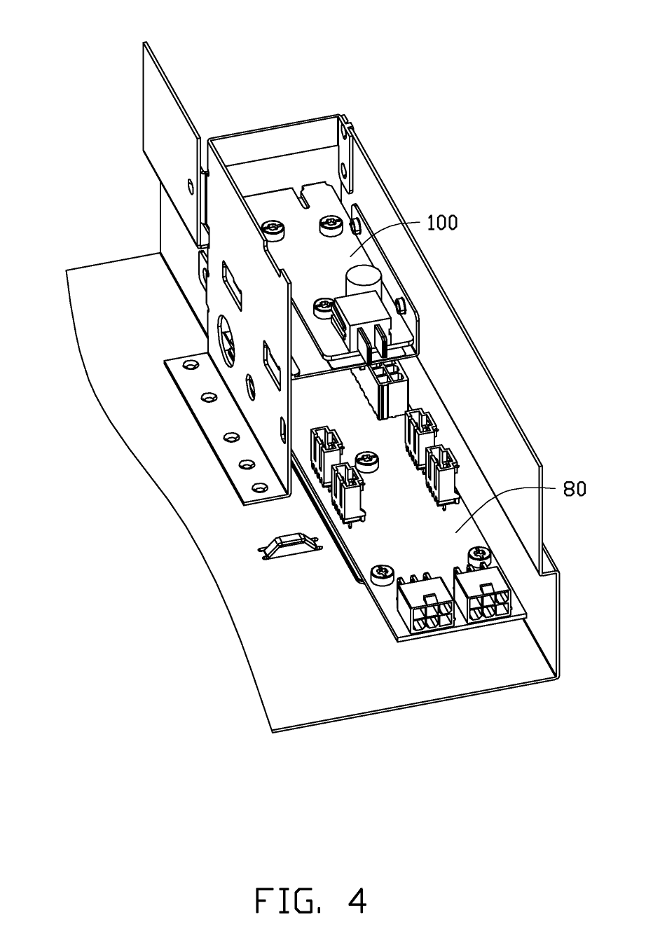

FIG. 4 and FIG. 5 illustrate two partial assembly views of the riser card assembly. The riser card assembly may further include an extending card 100. The extending card 100 is located on top of the riser card 80 and is substantially parallel to the riser card 80.

In other embodiments, to protect the edge connector 81, the edge connector 81 should not extend past the protecting board 55 of the tray 50.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. A riser card assembly comprising:
a chassis;
a bracket mounted to the chassis;
a tray, located in the chassis, the tray comprising a bottom plate and a protecting board extending from the bottom plate;
a riser card, comprising an edge connector, the riser card located on the tray and substantially parallel to the bottom plate, the riser card mounted to the chassis, and the protecting board being substantially flush with the edge connector; and
a mounting member fixed to the riser card, and the mounting member being fixed to the bracket.

2. The riser card assembly of claim 1, wherein a plurality of posts protrudes from the bottom plate, the riser card is fixed to the plurality of posts, and the riser card and the bottom plate are spaced by the plurality of posts.

3. The riser card assembly of claim 1, wherein an insulating sheet is located between the riser card and the bottom plate of the tray.

4. The riser card assembly of claim 1, wherein the chassis comprises a side wall, the bracket comprises a side panel, the side panel is substantially parallel to the side wall, the riser card is located between the side panel and the side wall, and the riser card is substantially perpendicular to the side panel.

5. The riser card assembly of claim 1, wherein the bracket further comprises a front panel, the bracket is fixed to the front panel, and the edge connector and the protecting board extend out of the front panel.

6. The riser card assembly of claim 5, wherein the mounting member is fixed to an inner side of the front panel.

7. The riser card assembly of claim 1, wherein the mounting member comprises a mounting tab and two mounting feet, the two mounting feet are fixed to the riser card, and the mounting tab is substantially perpendicular to the two mounting feet.

8. The riser card assembly of claim 1, wherein the mounting member is located adjacent to the edge connector of the riser card.

9. The riser card assembly of claim 1, wherein the chassis comprises a bottom wall, the riser card is substantially parallel to the bottom wall, and two posts protrude from the bottom wall, and the riser card is directly fixed to the two posts through two fasteners.

10. The riser card assembly of claim 9, wherein the two posts are located away from the edge connector of the riser card.

11. A riser card assembly comprising:
a chassis;
a bracket mounted to the chassis;
a tray located in the chassis, the tray comprising a bottom plate and a protecting board extending from the bottom plate;
a riser card, comprising an edge connector, the riser card located on the tray and substantially parallel to the bottom plate, the riser card mounted to the chassis, and the edge connector not exceed the protecting board; and
a mounting member fixed to the riser card, and the mounting member being fixed to the bracket.

12. The riser card assembly of claim 11, wherein a plurality of posts protrudes from the bottom plate, the riser card is fixed to the plurality of posts, and the riser card and the bottom plate are spaced by the plurality of posts.

13. The riser card assembly of claim 11, wherein an insulating sheet is located between the riser card and the bottom plate of the tray.

14. The riser card assembly of claim 11, wherein the chassis comprises a side wall, the bracket comprises a side panel, the side panel is substantially parallel to the side wall, the riser card is located between the side panel and the side wall, and the riser card is substantially perpendicular to the side panel.

15. The riser card assembly of claim 11, wherein the bracket further comprises a front panel, the bracket is fixed to the front panel, and the edge connector and the protecting board extend out of the front panel.

16. The riser card assembly of claim 15, wherein the mounting member is fixed to an inner side of the front panel.

17. The riser card assembly of claim 11, wherein the mounting member comprises a mounting tab and two mounting feet, the two mounting feet are fixed to the riser card, and the mounting tab is substantially perpendicular to the two mounting feet.

18. The riser card assembly of claim 11, wherein the mounting member is located adjacent to the edge connector of the riser card.

19. The riser card assembly of claim 11, wherein the chassis comprises a bottom wall, the riser card is substantially parallel to the bottom wall, and two posts protrude from the bottom wall, and the riser card is directly fixed to the two posts through two fasteners.

20. The riser card assembly of claim 19, wherein the two posts are located away from the edge connector.
